(19) United States
(12) Patent Application Publication
(10) Pub. No.: US 2018/0102924 A1
(43) Pub. Date: Apr. 12, 2018

(54) METHOD OF USING A DFE AS A SIGMA-DELTA ADC

(71) Applicant: Raytheon Company, Waltham, MA (US)

(72) Inventors: Brian A. Gunn, Waltham, MA (US); Russell Duren, Waltham, MA (US)

(73) Assignee: Raytheon Company, Waltham, MA (US)

(21) Appl. No.: 15/726,833

(22) Filed: Oct. 6, 2017

Related U.S. Application Data
(60) Provisional application No. 62/406,637, filed on Oct. 11, 2016.

(51) Int. Cl. H04L 25/03; H04L 25/02; H03M 3/00; H04L 25/06

(52) U.S. Cl. CPC H04L 25/03019; H04L 25/03949; H04L 2025/03496; H03M 3/414; H04L 25/063; H04L 25/0202

(57) ABSTRACT

A Decision Feedback Equalizer (DFE) is used as the predictive filter in a Sigma-Delta feedback loop as part of a Sigma-Delta Analog-to-Digital Converter. The tap weights of the DFE are chosen to provide adaptive noise shaping for receiving signals of various frequencies multiplexed in time.

### RELATED APPLICATION

This application is a non-provisional application claiming priority from U.S. Provisional Patent Application Ser. No. 62/406,637, filed Oct. 11, 2016 and entitled “Method of Using a DFE as a Sigma-Delta ADC,” the entire contents of which are incorporated by reference herein for all purposes.

### GOVERNMENT RIGHTS

N/A

### FIELD OF THE DISCLOSURE

The disclosure relates to using a Decision Feedback Equalizer (DFE) as a portion of an Analog-to-Digital Converter (ADC).

### BACKGROUND

Design choice decisions often include balancing trade-offs between size, weight and power (SWaP) and performance, among other things. FPGA devices are used to provide advantages for digital-based functions. When incorporating an Analog-to-Digital Converter (ADC) into a design, however, it is often the case that the ADC must be implemented separately from the FPGA device as FPGAs have limited functions when it comes to analog capabilities.

What is needed is a mechanism for leveraging the advantages of FPGA devices for analog functionalities.

### SUMMARY

According to one aspect of the disclosure, a method of processing an analog signal includes providing a Decision Based Equalizer (DFE) portion having an input and a plurality of gain/delay stages; setting a respective gain value for each gain/delay stage to a predetermined gain value; providing the analog signal to the DFE input; and retrieving a digital representation of the filtered analog signal at an output of the DFE.

According to one implementation, a respective delay value for at least one gain/delay stage may be set. Further, the respective gain values and delay values may be chosen to implement a filtering function, e.g., band-pass; low-pass; or high-pass.

According to another implementation, the respective gain and/or delay value for at least one gain/delay stage may be modified as a function of the provided analog signal. Alternately, the respective gain and delay values may be chosen to implement a predetermined filtering function to shape a noise power spectrum away from a signal of interest (SOI) in a received analog signal.

According to another aspect of the disclosure, a method of implementing a Sigma-Delta Analog-to-Digital Converter (ADC) using a Decision Based Equalizer (DFE) portion, wherein the DFE portion comprises an input and a plurality of gain/delay stages, comprises setting a respective gain value for each gain/delay stage to a predetermined gain value; providing an analog signal to the DFE input; and retrieving a digital representation of the analog signal at an output of the DFE.

### BRIEF DESCRIPTION OF THE DRAWINGS

Various aspects of the disclosure are discussed below with reference to the accompanying Figures. It will be appreciated that for simplicity and clarity of illustration, elements shown in the drawings have not necessarily been drawn accurately or to scale. For example, the dimensions of some of the elements may be exaggerated relative to other elements for clarity or several physical components may be included in one functional block or element. Further, where considered appropriate, reference numerals may be repeated among the drawings to indicate corresponding or analogous elements. For purposes of clarity, not every component may be labeled in every drawing. The Figures are provided for the purposes of illustration and explanation and are not intended as a definition of the limits of the disclosure. In the Figures:

FIG. 1 is a DFE portion of an FPGA; and

FIG. 2 is a method in accordance with an aspect of the disclosure.

### DETAILED DESCRIPTION

This application is a non-provisional application claiming priority from U.S. Provisional Patent Application Ser. No. 62/406,637, filed Oct. 11, 2016 and entitled “Method of Using a DFE as a Sigma-Delta ADC,” the entire contents of which are incorporated by reference herein for all purposes.

In the following detailed description, details are set forth in order to provide a thorough understanding of the aspects of the disclosure. It will be understood by those of ordinary skill in the art that these may be practiced without some of these specific details. In other instances, well-known methods, procedures, components and structures may not have been described in detail so as not to obscure the aspects of the disclosure.

It is to be understood that the disclosure is not limited in its application to the details of construction and the arrangement of the components set forth in the following description or illustrated in the drawings as it is capable of implementations or of being practiced or carried out in various ways. Also, it is to be understood that the phraseology and terminology employed herein are for the purpose of description only and should not be regarded as limiting.

Certain features, which are, for clarity, described in the context of separate implementations, may also be provided in combination in a single implementation. Conversely, various features, which are, for brevity, described in the context of a single implementation, may also be provided separately or in any suitable sub-combination.

In one aspect of the disclosure, a high-speed serial digital input of an FPGA is used to receive an analog signal into a Decision Feedback Equalizer (DFE). Using the high-speed serial inputs of an FPGA to receive an analog input has particular advantages in performance and hardware simplicity, due in part to the functions and configurability common for serial I/O inputs.

The Decision Feedback Equalizer (DFE) is included in many modern gigabit transceivers and is used to boost high frequencies that have been attenuated by channel loss and to reduce inter-symbol interference (ISI) for digital communications received at its input. Advantageously, aspects of the present disclosure re-purpose the gigabit transceiver to receive a wideband RF signal and uses the DFE as the predictive filter in a Sigma-Delta feedback loop as part of a Sigma-Delta ADC.

Sigma-Delta ADCs are effective due to their inherent analog linearity. The advantage of using the DFE block for this purpose is that it requires fewer components, thereby decreasing the cost and complexity of the hardware and it allows for easy and dynamic reconfiguration of the tap weights, i.e., gain and delay settings.

Using the DFE in this manner also provides adaptive noise shaping for receiving signals of various frequencies multiplexed in time. As will be described below, when using a DFE for Sigma-Delta sampling, the digital serial data is multiplied by a series of taps, i.e., gain/delay stages, and summed with the pre-sampled (analog) signal—providing an analog feedback. This configuration has numerous advantages: 1) no additional components, in conjunctions with the FPGA, are needed and 2) the tap weights can be modified on the fly with the implementation of adaptive algorithms for noise shaping/signal cancellation at varying frequencies.

As would be understood by one of ordinary skill in the art, the specific performance depends on the sampling rate and number and quantization of tap weights, however, it is expected that an input with an over-sampling rate (OSR) ˜10 would have >4 effective number of bits (ENOBs).

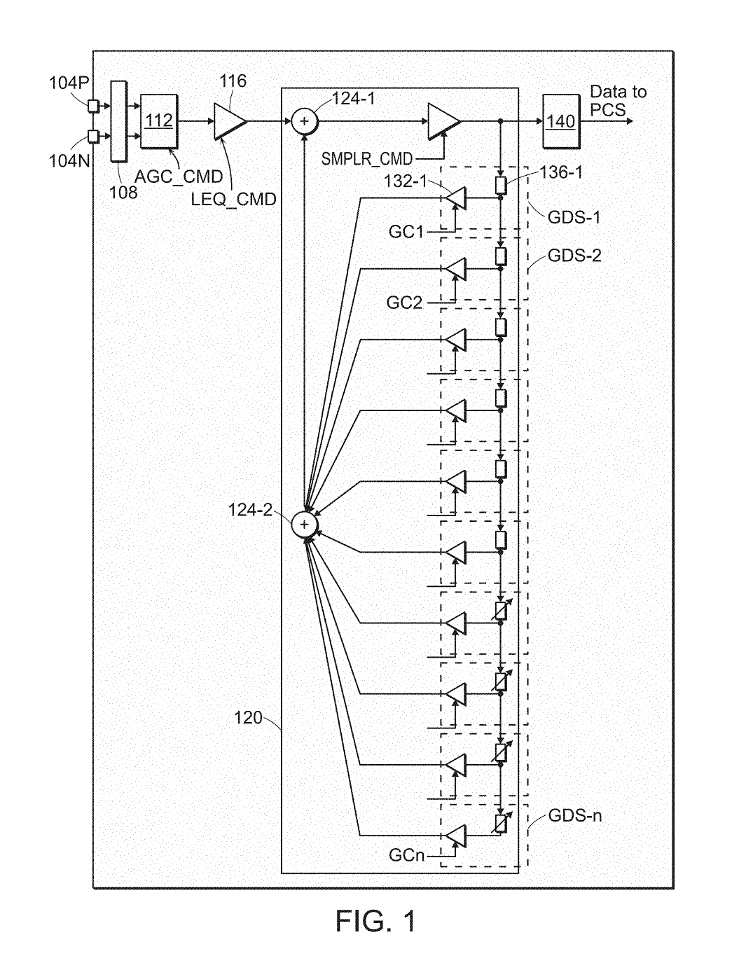

Referring now to FIG. 1, a portion of a commercially available FPGA, for example, a 7 Series FPGA GTX/GTH Transceiver from XILINX, San Jose, Calif., includes P/N inputs 104P, 104N for receiving an analog signal, through a termination block 108 and then to an Automatic Gain Control (AGC) module 112. The gain of the AGC 112 can be controlled by an AGC_CMD signal as known to those of ordinary skill in the art. An output of the AGC 112 is provided to a linear equalizer 116 that is controlled by an LEQ_CMD signal per known techniques. An output of the linear equalizer 116 is provided to an input of a Decision Feedback Equalizer (DFE) 120.

The DFE 120 includes first and second summing junctions 124-1, 124-2, a sampler 128 and a plurality of series-connected gain/delay (g/d) stages or “taps” GDS1, GDS2, . . . GDSn. Each g/d stage GDSx comprises a respective gain portion 132x and a respective delay portion 136x. The gain portion 136x is programmable by a respective GCx command value and the sampler 128 is controlled by a SMPLR_CMD signal. In each g/d stage GDSx, an output from the delay portion 136x is provided as an input to the corresponding gain portion 132x and the outputs from each gain portion 132x are input to the second summing junction 124-2.

The g/d stages GDSx are series-connected where the input of the delay portion 136-1 of the first g/d stage GDS-1 is coupled to the output of the sampler 128 and the output from each delay portion 136x, except for the last g/d stage GDS-n, is provided as an input to the delay portion 136x of the next g/d stage GDSx in the series. In some of the g/d stages GDSx, the amount of delay provided by the delay portion 136x is fixed whereas in some others of the g/d stages, the amount of delay is variable and selectable by the user.

An output of the second summing junction 124-2 is provided as an input to the first summing junction 124-1 to close the feedback loop.

By setting the gain control values GCx and/or the delay values appropriately, the DFE 120 will function as a Sigma-Delta ADC and the output from the sampler can be provided to a Serial-In Parallel-Out (SIPO) module 140 for placement on a digital bus for subsequent processing.

As the first summing junction 124-1 adds the feedback output to the input signal, instead of subtracting, the output of each of the g/d stages GDSx should be inverted. Accordingly, in one approach, each gain control value GCx would be the sample amplitude as the desired FIR coefficients, but negated. Alternatively, an inverter could be provided at the output of each g/d stage GDSx if a negative gain value is not allowed per the design parameters of the DFE. As another option, an inverting input could be provided on the first summing junction 124-1 or an inverter placed on the output of the second summing junction 124-2, as understood by one of ordinary skill in the art. Still further, if a particular g/d stage is pre-configured to not accept a negative gain value, then the gain for that stage would be set to zero and other stages set accordingly to provide the desired function.

Thus, the DFE-enabled high-speed digital receiver is leveraged as an over-sampled analog input. The DFE gain and/or delay values, i.e., the “tap weights,” can be chosen to shape the noise power spectrum away from the signal of interest (SOI) and may be dynamically, i.e., “on-the-fly,” reconfigured to change noise shaping, e.g., based on detected signals. Thus, the tap weights function to provide a programmable frequency response and summation. A minimally-equalized receiver for detection of signals can be used for this purpose or the signal can be “scanned” over a select set or range of frequencies.

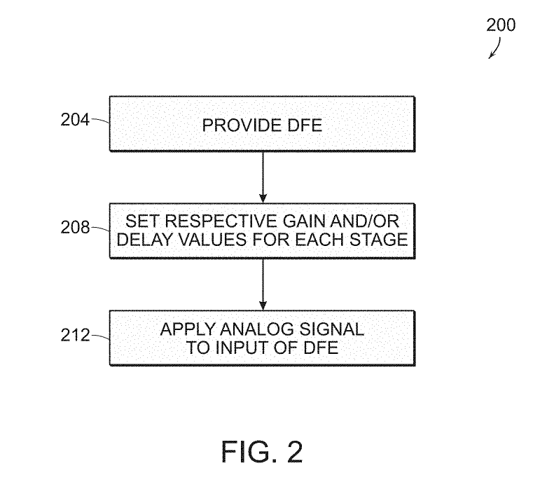

In another aspect of the disclosure, referring to FIG. 2, a method 200 of using a DFE for filtering an analog signal includes providing a Decision Based Equalizer (DFE) portion, step 204, as configured above. Subsequently, step 208, respective gain value and/or delay values for each gain/delay stage are set to predetermined values. The analog signal is provided to the DFE input, step 212, and a digital representation of the filtered analog signal at an output of the DFE is retrieved.

In one implementation, retrieving the desired signal includes digitally filtering the output of the DFE 120. A digital filter, not shown, will have a frequency response matching approximately a frequency response of the DFE 120. Further, and optionally, the digital data may be downsampled with no frequency ambiguity because of the reduced signal bandwidth.

In one implementation, the filtering and downsampling the output of the DFE 120 may be combined, e.g., a polyphase finite impulse response (FIR) filter/decimator is used.

Further, the respective gain and delay values may be chosen to implement a predetermined filtering function, e.g., band-pass; low-pass; or high-pass.

The respective gain or delay value for at least one gain/delay stage may be set as a function of the provided analog signal. Further, gain and/or delay values may be selected to shape the noise power spectrum away from the signal of interest (SOI) and may be dynamically, i.e., “on-the-fly,” reconfigured to change noise shaping, e.g., based on detected signals.

The present disclosure is illustratively described above in reference to the disclosed implementations. Various modifications and changes may be made to the disclosed implementations by persons skilled in the art without departing from the scope of the present disclosure as defined in the appended claims.

What is claimed is:

1. A method of processing an analog signal, the method comprising:
providing a Decision Based Equalizer (DFE) portion having an input and a plurality of gain/delay stages;
setting a respective gain value for each gain/delay stage to a predetermined gain value;
providing the analog signal to the DFE input; and
retrieving a digital representation of the filtered analog signal at an output of the DFE.

2. The method of claim 1, further comprising:
setting a respective delay value for at least one gain/delay stage.

3. The method of claim 2, wherein the respective gain values and delay values are chosen to implement a predetermined filtering function.

4. The method of claim 3, wherein the predetermined filtering function is one of:
band-pass; low-pass; or high-pass.

5. The method of claim 1, further comprising:
modifying the respective gain value for at least one gain/delay stage as a function of the provided analog signal.

6. The method of claim 2, further comprising:
modifying the respective delay value for at least one gain/delay stage as a function of the provided analog signal.

7. The method of claim 2, wherein the respective gain and delay values are chosen to implement a predetermined filtering function to shape a noise power spectrum away from a signal of interest (SOI) in the received analog signal.

8. The method of claim 1, further comprising:
digitally filtering the digital representation of the filtered analog signal with a digital filter.

9. The method of claim 8, wherein the digital filter has a frequency response matching approximately a frequency response of the DFE.

10. The method of claim 1, further comprising:
filtering and downsampling an output of the digital filter.

11. A method of implementing a Sigma-Delta Analog-to-Digital Converter (ADC) using a Decision Based Equalizer (DFE) portion, wherein the DFE portion comprises an input and a plurality of gain/delay stages, the method comprising:
setting a respective gain value for each gain/delay stage to a predetermined gain value;
providing an analog signal to the DFE input; and
retrieving a digital representation of the analog signal at an output of the DFE.

12. The method of claim 11, further comprising:
setting a respective delay value for at least one gain/delay stage.

13. The method of claim 12, wherein the respective gain values and delay values are chosen to implement a predetermined filtering function.

14. The method of claim 13, wherein the predetermined filtering function is one of:
band-pass; low-pass; or high-pass.

15. The method of claim 11, further comprising:
modifying the respective gain value for at least one gain/delay stage as a function of the provided analog signal.

16. The method of claim 12, further comprising:
modifying the respective delay value for at least one gain/delay stage as a function of the provided analog signal.

17. The method of claim 12, wherein the respective gain and delay values are chosen to implement a predetermined filtering function to shape a noise power spectrum away from a signal of interest (SOI) in the analog signal.

18. The method of claim 11, further comprising:
digitally filtering the digital representation of the filtered analog signal with a digital filter.

19. The method of claim 18, wherein the digital filter has a frequency response matching approximately a frequency response of the DFE portion as a function of the gain values of the gain/delay stages.

20. The method of claim 11, further comprising:
filtering and downsampling an output of the digital filter.

21. The method of claim 20, further comprising filtering and downsampling the digital filter output with a polyphase finite impulse response (FIR) filter/decimator.

22. The method of claim 10, further comprising filtering and downsampling the digital filter output with a polyphase finite impulse response (FIR) filter/decimator.
